(19) United States
(12) Patent Application Publication
(10) Pub. No.: US 2023/0294962 A1
(43) Pub. Date: Sep. 21, 2023

(54) METHOD AND DEVICE FOR CARRYING OUT AN AT LEAST PARTIALLY VIRTUALISED CONFORMITY ASSESSMENT FOR A PASSENGER TRANSPORT SYSTEM USING A DIGITAL DUPLICATED DATA SET

(71) Applicant: INVENTIO AG, (US)

(72) Inventor: Elena CORTONA, Zürich (CH)

(21) Appl. No.: 17/769,610

(22) PCT Filed: Oct. 14, 2020
(86) PCT No.: PCT/EP2020/078895

§ 371 Date: Apr. 15, 2022

(30) Foreign Application Priority Data
Oct. 18, 2019 (EP) 19203976.6

(51) Int. Cl. B66B 19/00; G06F 30/20

(52) U.S. Cl. CPC B66B 19/00; G06F 30/20; B66B 27/00

(57) ABSTRACT

The disclosure relates to carrying out a partially virtualized conformity assessment in a passenger transport system. The assessment is carried out according to a specified test protocol. A digital twin data record depicting an individually designed passenger transport system is created, in which data record physical properties of components of the passenger transport system are reproduced in a machine-processable manner. During the conformity assessment, it is checked whether properties of the passenger transport system correspond to target specifications. When carrying out the conformity assessment, at least some of the properties of the passenger transport system to be checked during the conformity assessment are determined as part of virtualized conformity assessment steps by deriving values from the digital twin data record or by simulations based on the digital twin data record, and indicated as virtual values in a results log.

### TECHNICAL FIELD

The present disclosure relates to a method and a device for carrying out a conformity assessment on a passenger transport system such as an elevator, an escalator or a moving walkway. The disclosure also relates to a computer program product designed to carry out the proposed method, and a computer-readable medium storing said computer program product.

Passenger transport systems in the form of elevators, escalators or moving walkways are used to convey passengers within buildings or structures.

### SUMMARY

Passenger transport systems that are to be newly built are generally initially designed during a planning phase. Physical properties are specified for each of a plurality of components that make up the passenger transport system. For example, a specific geometry, specific dimensions, specific materials, specific material properties, specific functionalities and/or the like can be specified as design-specific target properties for a component. In this way, the entire passenger transport system, including its components, can be designed so as to be individually customized for a specific purpose. The specific purpose can be characterized, for example, by boundary conditions at a place of use for the passenger transport system, requirements for functionalities of the passenger transport system, or properties of the passenger transport system desired by the user or specified by regulations, etc.

After the passenger transport system has been designed for its specific purpose, the individual components can be manufactured. The actual properties of a component that are realized during manufacturing should correspond as precisely as possible to the design-specific target properties of the component within an acceptable tolerance.

The manufactured components are then brought to the place of use where the passenger transport system is intended to be installed, and the passenger transport system is installed there by assembling the components.

Before the passenger transport system is put into operation or before the passenger transport system is handed over to a user, a so-called conformity assessment is usually carried out. During this conformity assessment, it is checked that the fully installed passenger transport system complies with specified requirements and/or functions in a desired manner.

Carrying out the conformity assessment is usually quite time-consuming. It also requires specially trained staff. Ultimately, the conformity assessment generates significant costs.

If the conformity assessment reveals that the passenger transport system does not meet certain requirements or that certain functionalities are not implemented in the desired manner, appropriate measures may have to be initiated. For example, components that have already been manufactured must be modified or changed components must be newly manufactured. If necessary, the modified or newly manufactured components must be brought to the place of use and installed there. This can result in considerable additional work and/or additional costs. In addition, there may be a delay in the completion of the passenger transport system. This delay can occur in particular at a point in time at which a customer is already waiting for the passenger transport system to be completed.

Moreover, as part of the conformity assessment, it is usually only possible to identify whether or how the fully installed passenger transport system does not meet certain requirements or certain functionalities are not implemented as desired. Reasons why these deficits occur cannot usually be determined. In particular, it is not possible to identify, for example, whether errors already occurred when designing the passenger transport system or whether the passenger transport system was designed correctly but errors then occurred during manufacturing of the components, or whether all of components were designed and manufactured correctly but ultimately installed incorrectly.

Therefore, inter alia, there may be a need for a method or a device by means of which the effort required for a conformity assessment to be carried out can be reduced, risks of errors occurring during the design, manufacturing and/or installation of components forming the passenger transport system can be reduced, and/or a root cause analysis can be simplified in the event that such errors are nevertheless detected. Furthermore, there may be a need for a device designed to carry out such a method, a computer program product for carrying out the method on a programmable device, and a computer-readable medium comprising such a computer program product stored thereon.

Such a need can be met by the subject matter according to any of the independent claims. Advantageous embodiments are defined in the dependent claims and in the following description.

According to a first aspect of the disclosure, a method for carrying out an at least partially virtualized conformity assessment on a passenger transport system is described. In this case, the conformity assessment is carried out according to a specified test protocol before the passenger transport system is handed over to a user. The passenger transport system was designed in advance so as to be individually customized for a specific purpose with a large number of components. A digital twin data record depicting the individually designed passenger transport system is created, in which data record physical properties of components of the passenger transport system are reproduced in a machine-processable manner. During the conformity assessment, it is checked whether properties of the passenger transport system correspond to predefined target specifications. These target specifications define at least a correct function of the components and/or a correct cooperation of the components with one another and/or safety-relevant properties of the passenger transport system. When carrying out the conformity assessment, at least some of the properties of the passenger transport system to be checked during the conformity assessment are determined as part of virtualized conformity assessment steps by deriving values from the digital twin data record or by simulations based on the digital twin data record, and indicated as virtual values in a results log. In this case, at least some of the properties of the passenger transport system to be checked during the conformity assessment are based on the physical properties of the components.

According to a second aspect of the disclosure, a device for carrying out an at least partially virtualized conformity assessment in a passenger transport system is proposed, wherein the device is configured to carry out or control a method according to an embodiment of the first aspect of the disclosure.

According to a third aspect of the disclosure, a computer program product is proposed which comprises machine-readable program instructions which, when executed on a programmable device, prompt the device to carry out or control a method according to an embodiment of the first aspect of the disclosure.

According to a fourth aspect of the disclosure, a computer-readable medium is proposed, on which a computer program product according to an embodiment of the third aspect of the disclosure is stored.

Possible features and advantages of embodiments of the disclosure can be considered, inter alia and without limiting the disclosure, to be based upon the concepts and findings described below.

In contrast to some other economic goods, passenger transport systems cannot generally be standardized in their entirety, i.e. they cannot be provided as products that are configured as standard. Instead, each passenger transport system is designed to be individually adapted for a specific purpose.

The specific purpose can be determined or influenced, for example, by specified conditions at a place of use, functionalities desired by a user and/or regulations to be observed. Parameters that define such a specific purpose can be, for example, dimensions of the passenger transport system, desired transport capacities, arrangements and properties of connection interfaces at which the passenger transport system is connected into a building to be supplied, properties to be implemented to ensure safe operation of the passenger transport system, etc.

A passenger transport system usually consists of a plurality of components that interact with one another. The components can, for example, comprise static components that are permanently installed on the building, dynamic components that can be moved relative to the building, drive components that can move the dynamic components, control components that control the drive components, monitoring components that monitor states in the passenger transport system, safety components that ensure safe operation of the passenger transport system, and other components.

During a design phase or when planning the passenger transport system, which is sometimes also referred to as commissioning, these components are designed or selected in such a way that the entire passenger transport system can ultimately be composed thereof and the passenger transport system thereby acquires the properties and functionalities established during the design phase.

As noted in the introduction, before starting normal operation of a passenger transport system or before handing over the passenger transport system to a user, it must usually be ensured that the physical properties and functionalities of the passenger transport system comply with previously defined specifications.

Traditionally, the passenger transport system is subjected to a conformity assessment after installation has been completed. During the conformity assessment, the entire passenger transport system is examined in terms of its physical properties and functionalities as part of various conformity assessment steps. The conformity assessment usually complies with a specified test protocol. In the test protocol, for example, a sequence of test steps to be carried out is specified, wherein for each of the test steps it is specified how this test step is to be carried out or which boundary conditions or properties of the passenger transport system are to be observed. The test protocol can, for example, be specified by a manufacturer of the passenger transport system. The test protocol is usually drafted in such a way that, when the test steps are carried out, it is checked in a technically meaningful way whether components of the passenger transport system function correctly, cooperate with other components and/or suitably contribute to the safe operation of the passenger transport system, for example.

Traditionally, all of the test steps of the conformity assessment are carried out on the real passenger transport system. The passenger transport system must therefore be fully installed before the conformity assessment is carried out. Accordingly, the conformity assessment can only establish whether the completed passenger transport system complies with the specifications and requirements. If this is not the case, however, it is not possible to retrospectively analyze why specifications or requirements are not met. In order to still be able to put the already installed passenger transport system into operation in such a case, it may also be necessary to subsequently modify or replace these or some of the components thereof, which may involve additional work and/or costs.

In order to avoid the disadvantages described, which can typically occur during the conventional conformity assessment, it is proposed, instead of or possibly in addition to a conformity assessment on the real, already completed passenger transport system, to carry out an at least partially virtualized conformity assessment in which, similarly to the conventional conformity assessment, it is checked whether properties of the passenger transport system correspond to target specifications; however, in contrast to the conventional conformity assessment, such a check is not or at least not exclusively carried out on the real, already completed passenger transport system, and is instead carried out with the aid of a digital twin data record (hereinafter sometimes also referred to as a digital twin for short).

As part of virtualized conformity assessment steps, values can be derived from the digital twin data record or determined by simulations based on information as contained in the digital twin data record. These values can indicate, for example, how physical properties and/or functionalities of the passenger transport system are configured. Since these values are not obtained through tests and/or measurements on the real passenger transport system, but are instead obtained by taking into account the digital twin data record, i.e. effectively on a virtual passenger transport system, they are also referred to herein as virtual values. These virtual values can then be indicated in a results log. By analyzing this results log, it can ultimately be determined whether the passenger transport system reproduced by the digital twin data record corresponds to the desired target specifications.

Since the proposed at least partially virtualized conformity assessment can be carried out at a point in time at which the passenger transport system has not yet been finally installed or even at a point in time at which the components which are intended to make up the passenger transport system have not yet been completed, it is possible to use the method proposed herein to identify, at a very early point in time, if the conformity assessment reveals deficiencies for the passenger transport system. It is thus also possible to start introducing countermeasures even at this early point in time. For example, a design of the passenger transport system can be adapted. It is therefore possible to avoid costs and work for faulty or unsuitable manufacturing of components and/or for the transport thereof to the place of use and/or installation at the place of use.

The physical properties to be taken into account when creating the digital twin data record can be, for example, geometric dimensions of the components, weights of the components, material properties of the components and/or surface characteristics of the components. In other words, a number of different types of physical properties of a component or of a plurality of components of a passenger transport system can be determined or predefined and then stored as data in the digital twin data record. Geometric dimensions of the components can be, for example, a length, a width, a height, a cross section, radii, fillets, etc. of the components. Material properties of the components can be, for example, a type of material used to form a component or a portion of a component. Furthermore, material properties can also be strength properties, hardness properties, electrical properties, magnetic properties, optical properties, elasticities etc. of the components. Surface characteristics of the components can be, for example, roughnesses, textures, coatings, colors, reflectivities, etc. of the components.

The physical component properties can relate to individual components or component groups. For example, the physical properties can relate to individual components which make up larger, more complex component groups. As an alternative or in addition, the properties can also relate to more complex equipment composed of a plurality of components, such as drive motors, gear units, conveyor chains, etc.

Values determined by simulations, which simulations are based on data from the digital twin data record, can represent the dynamic behavior of the movable components in various operating processes, such as acceleration values, deceleration values, vibration behavior (amplitudes and frequencies of the components and their changes over the travel distance), characteristic values and signals to be expected from virtually imaged sensors, which signals reproduce the correct interaction of the components, and the like.

According to one embodiment, as part of designing the passenger transport system, target design data can be created for components to be installed in the passenger transport system, which data indicate design-specific target properties of the relevant component.

The physical properties of a component can then be indicated in the digital twin data record on the basis of their target design data.

In other words, the data contained in the digital twin data record can reproduce target properties of the components or parts as recorded, for example, when planning, designing or commissioning the passenger transport system and as can be taken, for example, from CAD data used herein that relate to the components or parts. These target properties of the components are also sometimes referred to below as target component properties, and the digital twin data record containing these data is also sometimes referred to as a configuration digital twin data record.

For example, when planning, designing or commissioning a passenger transport system, it is conventional to plan or design the components and parts used thereby with the aid of computers and using CAD programs, so that corresponding CAT data reproduce, for example, a target geometry of a part. However, CAD data of this kind that are used as target design data do not generally indicate what geometry a manufactured component actually has; manufacturing tolerances or the like, for example, can result in the actual geometry differing significantly from the target geometry. Furthermore, the target design data do not generally reproduce what physical properties a component ultimately has in the installed state.

The data contained in the digital twin data record are intended to reflect the physical target component properties of the components in sufficient detail to be able to derive statements therefrom about the structural and/or functional properties of the entire passenger transport system that are present in the finished passenger transport system. In particular, it is intended to be possible to derive statements about structural and/or functional properties which characterize a state and/or a functionality of the entire passenger transport system on the basis of the digital twin, which statements can be used for assessing the future operational properties of said system, in particular its future operational safety, its future availability and/or a future need for maintenance or repair.

The configuration digital twin data record thus represents a virtual image of the passenger transport system in its planning phase or commissioning phase, i.e. before the passenger transport system is actually manufactured and installed.

In this case, creating the configuration digital twin data record can comprise creating configuration data while taking into account customer specifications and creating manufacturing data by modifying the configuration data and taking into account manufacturing specifications. In other words, both customer specifications and manufacturing specifications can be taken into account when initially creating the configuration digital twin data record. Generally, the configuration data are first created by taking into account the customer specifications, and these configuration data are then modified or refined while taking into account the manufacturing specifications. Creating the configuration digital twin data record can also optionally iteratively comprise calculating and modifying configuration data multiple times while taking into account the customer and/or manufacturing specifications.

Customer specifications can be understood to mean specifications which are specified by the customer in individual cases, for example when ordering the passenger transport system. The customer specifications typically relate to a single passenger transport system to be manufactured. For example, the customer specifications can comprise prevailing spatial conditions at the place of installation, interface information for attachment to supporting structures of a building, etc. In other words, the customer specifications can indicate, for example, what length the passenger transport system is intended to be, what height difference is intended to be overcome, how the passenger transport system is intended to be connected to supporting structures within the building, etc. Customer specifications can also comprise customer wishes with regard to functionality, conveying capacity, visual look, etc. The configuration data can be present, for example, as a CAD data record which, inter alia, reproduces geometric dimensions and/or other physical properties of the parts forming the passenger transport system.

The manufacturing specifications typically relate to properties or specifications within a manufacturing factory or manufacturing line in which the passenger transport system is intended to be manufactured. For example, depending on the country or location in which a manufacturing factory is located, various conditions may exist and/or requirements may have to be met in the manufacturing factory. For example, specific materials, raw materials, raw components or the like may not be available or may not be processed in some manufacturing factories. In some manufacturing factories, machines can be used that are not available in other manufacturing factories. Due to their layout, some manufacturing factories are subject to restrictions with regard to the passenger transport systems or components thereof to be manufactured therein. Some manufacturing factories allow for a high degree of automated production, whereas other manufacturing factories use manual production, for example due to low labor costs. There may be a large number of other conditions and/or specifications with respect to which manufacturing environments can differ. All of these manufacturing specifications typically have to be taken into account when planning or commissioning a passenger transport system, since the way in which a passenger transport system can actually be built can depend thereon. If necessary, it may be necessary to fundamentally modify the initially created configuration data, which only took into account the customer specifications, in order to be able to take into account the manufacturing specifications.

The digital twin data record can be stored, analyzed and/or processed in a computer configured for carrying out the method proposed herein or in a corresponding data processing system. Moreover, simulation programs can optionally be executed in the computer, by means of which programs properties and/or functionalities of the passenger transport system represented by the digital twin data record can be simulated using the data in the digital twin data record. In particular, the computer or the data processing system can be arranged remotely from the passenger transport system to be inspected, for example in a remote monitoring center or in a data cloud.

According to one embodiment, as part of manufacturing a component of the passenger transport system that is to be installed in the passenger transport system, actual manufacturing data can be determined which indicate actual properties of the relevant component that are realized during manufacturing. The physical properties of the component can then be indicated in the digital twin data record on the basis of their actual manufacturing data.

In other words, the conformity assessment can be carried out on the basis of a digital twin data record in which target design data do not or do not only reproduce the target properties of the components, but instead or in addition actual manufacturing data are recorded in the digital twin data record. These actual manufacturing data do not specify any target properties specified during design, but instead reflect the actual properties of a component that actually occur during the manufacturing of a component.

The actual manufacturing data can be determined, for example, by measuring an actually manufactured component. Since the actual properties can differ from the target properties, for example due to tolerances during manufacturing, the digital twin data record supplemented with actual manufacturing data can reproduce the physical properties of the components of the passenger transport system more precisely than is the case with the design digital twin data record. Accordingly, the virtual values can be determined more precisely for the results log.

The actual manufacturing data can be determined at a point in time at which a component has already been manufactured but not yet installed in the passenger transport system. Accordingly, the at least partially virtualized conformity assessment can be carried out at an early point in time, in particular before components are transported to a place of use and/or installed there. Should errors be discovered in the design and/or manufacturing of components, measures can be taken early and transport costs and/or installation costs can therefore be saved.

According to a further embodiment, as part of installing components of the passenger transport system that are to be installed in the passenger transport system in the passenger transport system, actual installation data can be determined which indicate actual properties of the relevant component that are realized during installation. The physical properties of the component can be indicated in the digital twin data record on the basis of their actual installation data.

In other words, instead of or in addition to target design data and/or actual manufacturing data, so-called actual installation data can be contained in the digital twin data set that is used for the conformity assessment. These actual installation data reproduce actually occurring physical properties of the components contained in the passenger transport system at a stage in which the components have already been installed in the passenger transport system.

Similar to the actual manufacturing data, the actual installation data can also be determined by measuring a finished component, but after it has been installed. Since the physical properties of a component can be modified by the installation of said component, the digital twin data record supplemented with the actual installation data can reproduce the physical properties of the components in the fully installed passenger transport system more precisely than is the case, for example, with the design digital twin data record or the manufacturing digital twin data record. Accordingly, the virtual values can more accurately reproduce the actual properties of the passenger transport system in its fully installed state for the results log.

According to one embodiment, all of the properties of the passenger transport system to be checked during the conformity assessment can be derived from the digital twin data record or can be determined by simulations based on the digital twin data record.

In other words, the conformity assessment can be carried out in a completely virtualized manner, i.e. all of the properties of the passenger transport system to be determined can be determined exclusively by analyzing the information contained in the digital twin data record or by simulations using the data in the digital twin data record. The virtualized conformity assessment can therefore be carried out at a point in time at which the passenger transport system has already been completely designed and therefore, for example, target component properties have been established for each of the components to be installed therein, but no components have actually yet been manufactured and/or installed. If errors or deficits in the passenger transport system are determined in this purely virtualized conformity assessment, these can be counteracted at an early stage and costs and/or work for manufacturing, transport and/or installation that would otherwise be carried out can be avoided.

Alternatively or additionally, according to one embodiment, the passenger transport system can have a controller as one of its components, by means of which controller other components of the passenger transport system can be controlled. In the conformity assessment, a so-called “hardware in the loop” approach, a real existing controller can then communicate with a computer in which the components to be controlled are simulated on the basis of data from the digital twin data record, in order to virtually control the simulated components. The properties of the passenger transport system to be checked during the conformity assessment can then be derived from physical properties of the real existing controller and from physical properties of the components as indicated in the digital twin data record or as to be determined by simulations based on the digital twin data record.

In this embodiment, the conformity assessment is therefore carried out in a not completely virtualized manner, i.e. not carried out completely on the basis of the digital twin data record. Instead, at least the controller of the passenger transport system exists as a real component, while some or all of the other components of the passenger transport system do not yet actually exist and are instead represented by their digital twin. The components that do not actually exist can then be reproduced or simulated in a computer. The real controller can communicate with this computer, for example via a data interface. For example, the real controller can transmit control signals or control commands to the computer via the data interface, and the components simulated on the basis of the digital twin data record can then be controlled virtually in the computer using these control signals or control commands By controlling the simulated components in a targeted manner, for example, functionalities of the entire passenger transport system can be simulated, and these can be analyzed as part of the partially virtualized conformity assessment. In this way it can be checked, for example, whether the real existing controller operates in a desired way and can communicate as desired with the otherwise virtually existent remainder of the passenger transport system and its components.

According to one embodiment, properties to be checked that cannot be derived or cannot be sufficiently derived solely on the basis of information contained in the digital twin data record can be indicated with predefined default properties in the results log.

In other words, those of the properties to be checked as part of the conformity assessment that cannot be determined solely virtually or at least not in a sufficient manner can be indicated in the results log so as to be represented by default properties, i.e. so-called default values.

“Not sufficiently derived from the digital twin data record” can in this case be understood to mean that no sufficiently reliable and/or sufficiently accurate conclusion about particular physical properties to be checked can be drawn from the digital twin data record alone or from simulations using the digital twin data record.

For example, as part of a conformity assessment, it may be necessary to carry out emergency braking and then examine brake marks, for example on a guide rail of an elevator system. Such an analysis of emergency braking is difficult to carry out, or at least cannot be carried out in a sufficiently reliable manner. In order to still be able to complete the conformity assessment, a predefined default value can be recorded in the results log for the properties to be checked in this case, i.e. the behavior to be checked as a result of an analysis of the brake marks for emergency braking.

According to a more specific embodiment, those properties which cannot be derived or cannot be sufficiently derived solely on the basis of information contained in the digital twin data record can be specifically characterized in the results log.

In this way, it is possible to later identify in the results log which of the virtual values recorded therein were not derived from data of the digital twin data record or were simulated by means thereof, and instead only predefined default properties can be indicated.

According to one embodiment, in addition to the partially virtualized conformity assessment, a reality-based conformity assessment can also be carried out after completion of the passenger transport system, in which reality-based conformity assessment all of the properties of the passenger transport system to be checked during the conformity assessment are determined on the real passenger transport system and additionally indicated as real values in the results log.

In other words, in addition to a partially virtualized conformity assessment possibly carried out at an earlier point in time, a reality-based conformity assessment corresponding to the conventional conformity assessments can also be carried out. The physical properties of the passenger transport system are determined on the real, fully installed passenger transport system, for example by means of appropriate physical tests and/or measurements. The physical properties found in this process can then be recorded in the results log in addition to the virtual values previously determined by means of the virtual conformity assessment, and can be used as real values reproducing the real physical properties of the passenger transport system.

Additionally, according to one embodiment, the virtual values can advantageously be compared with the real values in the results log in order to identify deficits in the design and/or implementation of the passenger transport system, also with respect to passenger transport systems to be created in the future.

In other words, in the event that both an at least partially virtualized conformity assessment and a reality-based conformity assessment are carried out, the virtual values determined in this process can be compared with the real values that have also been determined. In particular, if there are differences between these values, this can suggest deficiencies or errors in the design and/or in the implementation, i.e. in the manufacturing of the components and/or the installation of the components. These results can then be incorporated into product lifecycle management in order to improve its processes.

According to a specific embodiment of the disclosure, the passenger transport system is an escalator or a moving walkway. In this case, the components of the passenger transport system are preferably parts of a framework and parts of a conveying apparatus. The components of a framework can be upper chords, lower chords, uprights, transverse struts, diagonal struts, gusset plates, support brackets and/or framework separation points. The components of a conveying apparatus can be escalator steps, moving walkway pallets, conveyor chains, conveyor belts, drive machines, service brakes and/or controllers.

In other words, a passenger transport system in the form of an escalator or moving walkway can be composed of a plurality of components or parts which both form a framework that represents a supporting structure of the passenger transport system and form a conveying apparatus which is held by the framework and by means of which passengers can be transported along a travel path. The properties of both the framework and the conveying apparatus should be checked by means of a conformity assessment prior to being put into operation, for example in order to establish or be able to ensure functionalities that can be important for operational safety and/or availability of the escalator or moving walkway.

Creating the current digital twin data record for the escalator or moving walkway and checking properties of same can be the same as is alternatively described here for the embodiment in which the passenger transport system is an elevator.

According to an alternative embodiment of the disclosure, the passenger transport system is an elevator. The components of the passenger transport system can be parts of a support structure and/or parts of a conveyor structure. The components of the support structure can be guide rails, wall fastenings, support frames, floor fastenings, transverse struts, longitudinal struts and/or diagonal struts. The components of a conveyor structure can be elevator cars, counterweights, suspension means, drive machines, braking devices and/or controllers.

Specific configurations of how a current digital twin data record can be created for an elevator and how properties of the elevator can be checked on the basis thereof by means of an at least partially virtualized conformity assessment are set out below with reference to preferred embodiments.

Embodiments of the method presented herein for carrying out an at least partially virtualized conformity assessment in a passenger transport system can be carried out by means of a device specifically configured for such a purpose. The device can comprise one or more computers. In particular, the device can be formed from a computer network which processes data in the form of a data cloud. For this purpose, the device can have a memory in which the data of the digital twin data record can be stored, for example in electronic or magnetic form. In addition, the device can have data processing options. For example, the device can have a processor by means of which data of the digital twin data record can be processed. The device can also have interfaces via which data can be input into the device and/or output from the device. The device can optionally be connected to sensors which are arranged on or in the passenger transport system and by means of which physical properties of parts of the passenger transport system can be measured. In principle, the device can be part of the passenger transport system. However, the device is preferably not arranged in the passenger transport system, but instead remotely therefrom, for example in a remote control center from which the state of the passenger transport system is intended to be monitored. The device can also be implemented in a spatially distributed manner, for example if data are processed in a data cloud in a manner distributed over a plurality of computers.

In particular, the device can be programmable, i.e. it can be prompted by a suitably programmed computer program product to execute or control the method according to the disclosure. The computer program product can contain instructions or code which, for example, prompt the processor of the device to store, read, process and modify data of the digital twin data record and to carry out simulations based thereon. The computer program product can be written in any computer language.

The computer program product can be stored on any computer-readable medium, for example a flash memory, a CD, a DVD, RAM, ROM, PROM, EPROM, etc. The computer program product and/or the data to be processed thereby can also be stored on a server or a plurality of servers, for example a data cloud, from where they can be downloaded via a network, for example the Internet.

Finally, it must be noted that some of the possible features and advantages of the disclosure are described herein with reference to different embodiments of both the proposed method and the correspondingly designed device for carrying out an at least partially virtualized acceptability check in a passenger transport system. A person skilled in the art recognizes that the features can be combined, transferred, adapted or replaced as appropriate in order to arrive at further embodiments of the disclosure.

### BRIEF DESCRIPTION OF THE DRAWINGS

An embodiment of the disclosure will be described below with reference to the accompanying drawings, with neither the drawings nor the description being intended to be interpreted as limiting the disclosure.

FIG. 1 shows a passenger transport system in the form of an elevator, with respect to which a method according to the disclosure can be carried out. FIG. 1 is merely schematic and not to scale. The same reference signs indicate the same or equivalent features.

### DETAILED DESCRIPTION

First, a passenger transport system to be checked as part of a conformity assessment is described briefly and only very schematically with regard to the components and parts used therein.

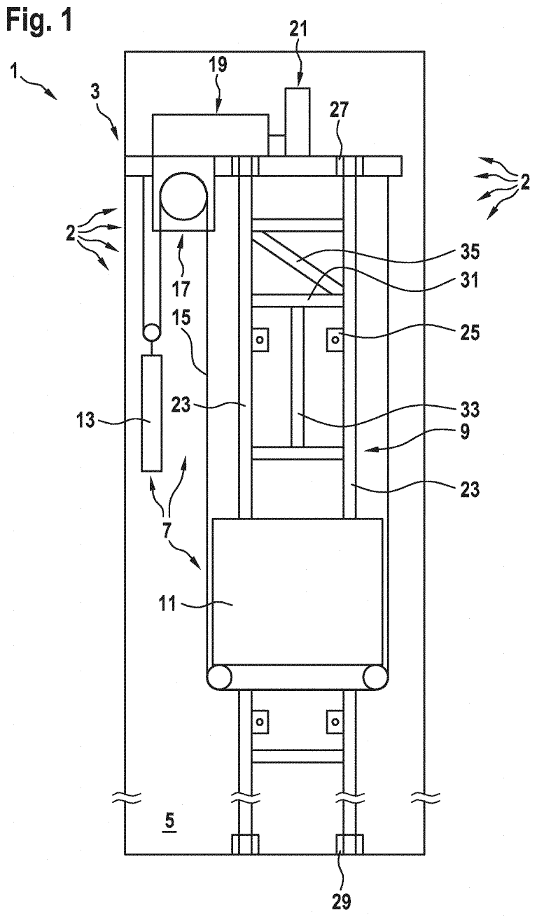

As shown in FIG. 1, in one embodiment the passenger transport system 1 is designed as an elevator 3. The elevator 3 has an elevator shaft 5 in which a conveying apparatus 7 and a support structure 9 holding this conveying apparatus 7 are housed. An elevator car 11 and a counterweight 13 are suspended from suspension means 15 in the form of belts. A drive machine 17 and a braking device 19 drive the suspension means 15 or brake them if necessary. A controller 21 controls the operation of the elevator 3, in particular of its drive machine 17 and its braking device 19. The elevator car 11 and optionally also the counterweight 13 are guided by guide rails 23 as they move through the elevator shaft 5. The guide rails 23 are connected to supporting structures within the elevator shaft 5 via wall fastenings 25, support frames 27 and floor fastenings 29. Furthermore, cross struts 31, longitudinal struts 33 and diagonal struts 35 may ensure sufficient mechanical stabilization of the guide rails 23. The apparatuses mentioned by way of example and potentially any further apparatuses are also referred to herein as components 2 (only shown schematically by a reference sign in FIG. 1) of the passenger transport system 1.

Elevators 3 are traditionally designed so as to be individually customized for a specific purpose. During a design phase, the components 2 required for an individual elevator 3 are planned in terms of their physical target properties so as to be adapted, for example, to the conditions in the building to be supplied with the elevator 3, to a specification sheet drawn up by an operator in which requirements for functionalities, conveying capacities and the like are indicated, and to specifications regulated by regulations or laws. The design and the configuration of the components 2 carried out in the process are mostly carried out by means of a computer. The computer can have access to a database in which physical properties of pre-assembled components and/or of components that can be produced for individual purposes are stored. In addition or as an alternative, a CAD program, for example, can be used on the computer in order to be able to design the components and their target component properties.

The components designed in this way are then manufactured, transported to the place of use and lastly installed there, i.e. connected to one another and integrated into the building to be supplied.

Before the passenger transport system 1 is handed over to the operator and put into operation, it is generally subjected to a conformity assessment. It is then checked, in accordance with a test protocol, whether the passenger transport system 1 corresponds to predefined target specifications.

In the example of an elevator 3 shown above, as part of the conformity assessment it can be checked, for example, whether the components 2 of the support structure 9, i.e. in particular the transverse, longitudinal and diagonal struts 31, 33, 35 and the wall, ceiling and floor fastenings 25, 27, 29 have been correctly dimensioned, can interact correctly and have been correctly installed in order to achieve target physical properties such as mechanical resistance. Physical properties of the elevator car 11, the counterweight 13, the suspension means 15 connecting these, the drive machine 17 driving the suspension means 15, the braking devices 19 and functions of the controller 21 controlling these components 2 can also be determined or checked by various tests to be carried out during the conformity assessment. For example, the controller 21 can control the drive machine 17 to move the elevator car 11 and the counterweight 13 to specific positions and/or at specific speeds and it can be checked whether the movements are being carried out as required. Braking processes, which are particularly essential for the safe operation of the elevator 3, can also be controlled in a targeted manner and it can be checked whether the braking processes are being carried out as required.

In order to be able to carry out the conformity assessment not only after the passenger transport system 1 has been fully installed, a method for carrying out an at least partially virtualized conformity assessment is proposed.

For this purpose, a digital twin data record depicting the individually designed passenger transport system 1 is created. Physical properties of components 2 of the passenger transport system 1 are reproduced in the digital twin data record in a machine-processable manner.

For example, the data that were established in the design phase as target design data for the components 2 of the individual passenger transport system 1 can be recorded in the digital twin data record for this purpose. Specifically, the digital twin data record can be created for the passenger transport system 1 using the CAD data determined during the design phase.

By way of explanation using the example of the above passenger transport system 1 in the form of the elevator 3, data relating to physical properties of the various fastenings 25, 27, 29 and struts 31, 33, 35 such as data on geometries, dimensions, materials used and their material properties, surface characteristics and the like can be recorded in the digital twin data record, for example. Similar data can also be recorded in the digital twin data record for the elevator car 11, the counterweight 13 and the suspension means 15. In addition to this data, it is also possible to record data for the drive machine 17, the braking devices 19 and the controller 21 in the digital twin data record, which data relates, for example, to an electrical configuration of these components 2 and/or also relates, for example, to functionalities as intended to be realized by these components 2.

Further possibilities and details regarding the creation of a digital twin data record and the subsequent possible uses thereof are set out in an earlier patent application WO 2019/115378 A1 from the applicant of the present patent application, and can also be used in a similar or adapted manner for the creation of a digital twin data record as can be used for the present disclosure. The content of the earlier application is therefore incorporated in full into the present application by way of reference.

Using the previously generated digital twin data record, it is possible, as part of the partially virtualized conformity assessment before the passenger transport system is completed or even before its components have been manufactured, to check whether, on the basis of the physical properties of the components used in the design of the passenger transport system, which properties are reproduced in the digital twin data record, it can be assumed that the resulting properties of the passenger transportation system manufactured therewith satisfy predefined target specifications.

For this purpose, values can be derived from the digital twin data record, which values provide information about the properties of the passenger transport system that are to be checked. Alternatively or in addition, computer simulations can be carried out using the data contained in the digital twin data record, in which computer simulations properties of the passenger transport system are simulated and values are determined therefrom which reproduce these properties to be checked.

The determined values can then be stored as virtual values in a results log. By analyzing these values, it can ultimately be decided, for example, whether the passenger transport system 1 was designed correctly.

In contrast to a conventional conformity assessment, the passenger transport system 1 preferably does not yet completely exist as a physical apparatus at the point in time at which the method presented here is carried out. Instead, at least parts of the passenger transport system 1 only exist as a virtual model and are reproduced by the digital twin of the passenger transport system 1.

In the digital twin data record, the components 2 that form these parts of the passenger transport system 1 can, however, be reproduced or modeled precisely enough with regard to their physical properties that the conformity assessment can be carried out with the aid of the virtual model in a similar manner as was the case with the conventional reality-based conformity assessment. In particular, individual conformity assessment steps can be carried out on the virtual model or with the aid of the virtual model in a similar manner as is the case with the reality-based conformity assessment. The same or a similarly adapted test protocol can be followed as for the reality-based conformity assessment.

If desired, the results log generated by the partially virtualized conformity assessment can be improved by the virtual values determined therefor not only based on target design data that indicate design-specific target properties of components, but also or alternatively based on actual manufacturing data that indicate actual properties of the respective components that are realized during manufacturing or possibly even based on actual installation data that indicate actual properties of the respective components that are realized during installation. As a result, it is possible to take into account in the digital twin data record that, when manufacturing components and/or installing same, there may be differences in their physical properties by comparison with the target properties indicated in the target design data. A virtualized conformity assessment based on the digital twin data record provided with the actual data can thus provide even more precise information as to whether properties of the passenger transport system correspond to target specifications.

If certain properties to be checked cannot be reliably derived or cannot be derived with sufficient accuracy as part of the at least partially virtualized conformity assessment, predefined default properties (“default values”) can be indicated in the results log for these properties. This may be specifically characterized in the results log in order to simplify later evaluation and in particular to be able to identify that some of the values in the results log are not actual results of a conformity assessment step that can be reliably carried out.

If necessary, in addition to one or more at least partially virtualized conformity assessments, a reality-based conformity assessment can also be carried out after completion of the passenger transport system 1 and the properties of the passenger transport system determined in the process can be indicated as real values in the results log. These real values can then be compared with the virtual values in order to be able to identify deficits in the design and/or manufacturing and/or installation of components 2 for the passenger transport system 1. For this purpose, deviation criteria can be stored in the digital twin data record, and, if these criteria are exceeded, the corresponding determined values are highlighted as deficient in the results log.

Using the approach described herein of an at least partially virtualized conformity assessment, various other advantages can be achieved in addition to the already described possibility of being able to identify deficits or errors in the design, manufacturing and/or installation of components of the passenger transport system. For example, the virtual values recorded in the results log can be stored in the digital twin data record and then used over the lifetime of components or apparatus parts in order to be able to detect changes and in particular deteriorations. The quality of components and apparatuses parts can be consistently increased, since potential problems can be detected very early, ideally before material is transported to the place of use, for example. If necessary, properties of apparatus parts can also be easily reproduced on the basis of very clear criteria. In addition, the fact that virtual values and real values from the results log may be compared with one another can ideally be used to derive a pattern which indicates which of the tests carried out during the conformity assessment may not be relevant, since, for example, their results always correspond to the target specifications. It is also possible to derive indications as to which properties that can lead to problems should also be tested. Altogether, the use of the data from the digital twin of the passenger transport system enables various types of analyzes.

For a manufacturer of a passenger transport system, this makes high product quality possible as a result of it being possible to identify problems in the planning and manufacturing of the passenger transport system early. For example, problems can be identified during configuration and corrected at an early stage, which can save installation and commissioning time. It is also possible to achieve better traceability by comparing the results from the virtual conformity assessment with those from the reality-based conformity assessment for each specific installation. Finally, an analysis of large amounts of data (big data analysis) is also made possible, in which analysis, for example, the digital twin data record and the values in the results log can be assigned to a very detailed product configuration.

Finally, it should be noted that terms such as “comprising”, “having”, etc. do not preclude other elements or steps and terms such as “a” or “an” do not preclude a plurality. Furthermore, it should be noted that features or steps that have been described with reference to one of the above embodiments may also be used in combination with other features or steps of other embodiments described above. Reference signs in the claims should not be considered to be limiting.

1. A method for carrying out an at least partially virtualized conformity assessment on a passenger transport system, the method comprising:
performing a conformity assessment according to a specified test protocol before providing the passenger transport system to a user, wherein the passenger transport system was designed in advance so as to be individually customized for a specific purpose with a plurality of components,
wherein a digital twin data record depicting the individually designed passenger transport system is created, in which data record physical properties of components of the passenger transport system are reproduced in a machine-processable manner,
wherein, during the conformity assessment, it is checked whether the properties of the passenger transport system correspond to target specifications which define at least a correct function of the components and/or a correct cooperation of the components with one another and/or safety-relevant properties of the passenger transport system, and
wherein, when carrying out the conformity assessment, at least some of the properties of the passenger transport system that are to be checked during the conformity assessment and are based on physical properties of components are determined as part of virtualized conformity assessment steps by deriving values from the digital twin data record or by simulations based on the digital twin data record, and indicated as virtual values in a results log.

2-15. (canceled)

16. The method of claim 1, wherein, as part of designing the passenger transport system, target design data are created for components to be installed in the passenger transport system, which data indicate design-specific target properties of the relevant component, and wherein the physical properties of a component are indicated in the digital twin data record on the basis of their target design data.

17. The method of claim 1, wherein, as part of manufacturing a component of the passenger transport system that is to be installed in the passenger transport system, actual manufacturing data are determined which indicate actual properties of the relevant component that are realized during manufacturing, and wherein the physical properties of the component are indicated in the digital twin data record on the basis of their actual manufacturing data.

18. The method of claim 1, wherein, as part of installing components of the passenger transport system that are to be installed in the passenger transport system in the passenger transport system, actual installation data are determined which indicate actual properties of the relevant component that are realized during installation, and wherein the physical properties of the component are indicated in the digital twin data record on the basis of their actual installation data.

19. The method of claim 1, wherein all of the properties of the passenger transport system to be checked during the conformity assessment are derived from the digital twin data record or are determined by simulations based on the digital twin data record.

20. The method of claim 1, wherein:
the passenger transport system has, as one of its components, a controller by means of which other components of the passenger transport system can be controlled,
during the conformity assessment, a real existing controller communicates with a computer in which the components to be controlled are simulated on the basis of data from the digital twin data record, in order to virtually control the simulated components, and
the properties of the passenger transport system to be checked during the conformity assessment are derived from physical properties of the real existing controller and from physical properties of the components as indicated in the digital twin data record or as determined by simulations based on the digital twin data record.

21. The method of claim 1, wherein properties to be checked that cannot be sufficiently derived solely on the basis of information contained in the digital twin data record are indicated with predefined default properties in the results log.

22. The method of claim 21, wherein the properties which cannot be sufficiently derived solely on the basis of information contained in the digital twin data record are specifically characterized in the results log.

23. The method of claim 1, wherein, in addition to the partially virtualized conformity assessment, a reality-based conformity assessment is also carried out after completion of the passenger transport system, in which reality-based conformity assessment all of the properties of the passenger transport system to be checked during the conformity assessment are determined on the real passenger transport system and additionally indicated as real values in the results log.

24. The method of claim 23, wherein the virtual values are also compared with the real values in the results log in order to identify deficits in the design and/or the implementation of the passenger transport system.

25. The method of claim 1, wherein the passenger transport system is selected from a group comprising escalators and moving walkways, and wherein the components of the passenger transport system are selected from a group comprising:
components of a framework comprising a plurality of components selected from a subgroup comprising upper chords, lower chords, uprights, transverse struts, diagonal struts, gusset plates, support brackets and framework separation points; and
components of a conveying apparatus comprising at least one component selected from a subgroup comprising escalator steps, moving walkway pallets, conveyor chains, conveyor belts, deflection sprockets, deflection pulleys, drive machines, service brakes and controllers.

26. The method of claim 1, wherein the passenger transport system is an elevator and wherein the components of the passenger transport system are selected from a group comprising:
components of a support structure comprising a plurality of components selected from a subgroup comprising guide rails, wall fastenings, support frames, floor fastenings, transverse struts, longitudinal struts and diagonal struts; and
components of a conveying apparatus comprising at least one component selected from a subgroup comprising elevator cars, counterweights, suspension means, drive machines, braking devices and controllers.

27. A system for carrying out an at least partially virtualized conformity assessment in a passenger transport system, the system comprising:
at least one non-transitory computer storage medium comprising instructions; and
at least one processor that executes the instructions to:
perform a conformity assessment according to a specified test protocol before providing the passenger transport system to a user, wherein the passenger transport system was designed in advance so as to be individually customized for a specific purpose with a plurality of components,
wherein a digital twin data record depicting the individually designed passenger transport system is created, in which data record physical properties of components of the passenger transport system are reproduced in a machine-processable manner,
wherein, during the conformity assessment, it is checked whether the properties of the passenger transport system correspond to target specifications which define at least a correct function of the components and/or a correct cooperation of the components with one another and/or safety-relevant properties of the passenger transport system, and
wherein, when carrying out the conformity assessment, at least some of the properties of the passenger transport system that are to be checked during the conformity assessment and are based on physical properties of components are determined as part of virtualized conformity assessment steps by deriving values from the digital twin data record or by simulations based on the digital twin data record, and indicated as virtual values in a results log.

28. A non-transitory computer readable medium comprising instructions that configure a processor to:
perform a conformity assessment according to a specified test protocol before providing the passenger transport system to a user, wherein the passenger transport system was designed in advance so as to be individually customized for a specific purpose with a plurality of components,
wherein a digital twin data record depicting the individually designed passenger transport system is created, in which data record physical properties of components of the passenger transport system are reproduced in a machine-processable manner,
wherein, during the conformity assessment, it is checked whether the properties of the passenger transport system correspond to target specifications which define at least a correct function of the components and/or a correct cooperation of the components with one another and/or safety-relevant properties of the passenger transport system, and
wherein, when carrying out the conformity assessment, at least some of the properties of the passenger transport system that are to be checked during the conformity assessment and are based on physical properties of components are determined as part of virtualized conformity assessment steps by deriving values from the digital twin data record or by simulations based on the digital twin data record, and indicated as virtual values in a results log.
